(19) United States
(12) Patent Application Publication
(10) Pub. No.: US 2016/0024642 A1
(43) Pub. Date: Jan. 28, 2016

(54) PREHEAT CHAMBER OXIDATION PROCESS

(71) Applicant: UNITED TECHNOLOGIES CORPORATION, Hartford, CT (US)

(72) Inventor: Neil B Ridgeway, South Windsor, CT (US)

(21) Appl. No.: 14/774,907

(22) PCT Filed: Dec. 16, 2013
(86) PCT No.: PCT/US2013/075271

§ 371 Date: Sep. 11, 2015

Related U.S. Application Data
(60) Provisional application No. 61/781,484, filed on Mar. 14, 2013.

(51) Int. Cl. C23C 14/22; C23C 16/46; C23C 16/40; C23C 16/455

(52) U.S. Cl. CPC C23C 14/221; C23C 16/455; C23C 16/46; C23C 16/40

(57) ABSTRACT

A process for coating a part comprises the steps of: loading a bond coated part into a load chamber; moving the bond coated part from the load chamber to a preheat chamber; subjecting the bond coated part to a preheat treatment with controlled conditions to promote a specific thermally grown oxide layer to form; and moving the bond coated part with the thermally grown oxide layer to a electron beam physical vapor coating chamber for ceramic coating.

### BACKGROUND

The present disclosure is related to a process for coating a part such as a turbine engine component.

Prior to electron beam physical deposition (EB-PVD) of ceramic thermal barrier coatings of zirconia or zirconia containing materials, substrates forming the parts are bond coated. Often, the bond coat is formed from a MCrAlY material. After the bond coat is formed, the substrate with the bond coat is conditioned and preheated in a vacuum.

During the preheating treatment in the preheat chamber, and depending upon the environment, the substrate can develop a surface oxide. Typically, the preheat chamber maintains a hard vacuum to prevent oxidation during preheat. Instead of maintaining a protective atmosphere during preheat, the atmosphere can be controlled to develop specific oxides. This oxide is referred to as a thermally grown oxide (TGO). In the final product, this TGO resides at the interface between the bond coat and the ceramic thermal barrier or outer coating. The type, thickness, and quantity of the thermally grown oxide layer will influence the durability of the subsequently deposited thermal barrier coating. It can be said that the thermally grown oxide provides the critical link between the bond coat and the ceramic thermal barrier coating.

Alpha alumina is a desirable protective scale for most superalloys used for the substrates and for MCrAlY coatings. Alpha alumina forms at high temperatures as a well bonded scale which serves as a protective scale. Alpha alumina is a desirable phase of aluminum oxide for adhesion to the metallic substrate, along with cohesive strength. Additionally, ceramic coatings bond well to the thermally grown oxide on the bond coat. Complex oxides containing nickel, or cobalt, for example, create a TGO that can benefit the adhesion of ceramic coating that are not compatible with alumina TGOs.

Metastable oxides can form at the metallic-ceramic interface of a thermal barrier coating system. Such oxides can adversely affect coating durability. Complex or mixed oxide thermally grown oxides are poorly bonded, low integrity oxides and their presence at the bond coat-thermal barrier coating interface may adversely affect top coat (thermal barrier coating) adhesion.

Specific TGO formation requires process control to ensure proper formation or each coating run (i.e., controlled time, temperature, pressure and environment).

### SUMMARY

In accordance with the present disclosure, there is provided a process for coating a part which broadly comprises the steps of: loading a bond coated part into a load chamber; moving the bond coated part from the load chamber to a preheat chamber; subjecting the bond coated part to a preheat treatment which causes a thermally grown oxide layer to form; and moving said bond coated part with the thermally grown oxide layer to a coating chamber.

In another and alternative embodiment, the process further comprises backfilling the preheat chamber with a protective atmosphere.

In another and alternative embodiment, the backfilling step comprises backfilling the preheat chamber with carbon dioxide, moist hydrogen or moist argon as an oxidizer.

In another and alternative embodiment, the process further comprises pumping down pressure within said preheat chamber to a level less than 10⁻² Torr.

In another and alternative embodiment, the preheat treatment subjecting step comprises heating the part within the pretreatment chamber to a temperature in the range of 1800 to 2000 degrees Fahrenheit.

In another and alternative embodiment, the process further comprises flowing the protective atmosphere into the preheat chamber after the temperature has risen above 1800 degrees Fahrenheit.

In another and alternative embodiment, the protective atmosphere flowing step comprises flowing carbon dioxide or other oxidizing agent into the preheat chamber.

In another and alternative embodiment, the carbon dioxide or other oxidizing agent oxidizer is flowed into the preheat chamber at a rate while maintaining a pressure in the range of 10⁻² to 10⁻⁵ Torr with flows of 50 to 500 sccm.

In another and alternative embodiment, the TGO forming step comprises forming an alpha alumina TGO or a complex oxide of alumina layer.

In another and alternative embodiment, the process further comprises forming a coating over the thermally grown oxide layer.

In another and alternative embodiment, the coating forming step comprises forming a ceramic coating.

Further, in accordance with the present disclosure, there is provided a process for forming a bond coated part having a thermally grown oxide layer, comprising the steps of: providing a bond coated part; placing the bond coated part in a preheat chamber; and subjecting the bond coated part to a preheat treatment which causes a thermally grown oxide to form.

In another and alternative embodiment, the subjecting step comprises flowing a protective gas into the preheat chamber when temperature in the preheat chamber has reached at least 1800 degrees Fahrenheit.

In another and alternative embodiment, the flowing step comprises flowing carbon dioxide into the preheat chamber.

In another and alternative embodiment, the flowing step comprises flowing moist argon into the preheat chamber.

In another and alternative embodiment, the flowing step comprises flowing moist hydrogen into the preheat chamber.

In another and alternative embodiment, the flowing step comprises flowing the protective gas at a flow rate in the range of 50 to 500 sccm during an initial ramp up to 1800° F.

In another and alternative embodiment, the process further comprises backfilling the preheat chamber with the protective gas prior to heating the bond-coated part within the preheat chamber.

In another and alternative embodiment, the process further comprises creating a pressure in the range of from 10⁻² to 10⁻⁴ Torr within the preheat chamber after the backfilling step.

Other details of the preheat chamber oxidation process is set forth in the following detailed description and the accompanying drawings wherein like reference numerals depict like elements.

### BRIEF DESCRIPTION OF THE DRAWINGS

FIG. 1 is a schematic representation of a process for performing a coating process;

FIG. 2 is a schematic representation of a process for performing a coating process using a protective atmosphere in the preheat chamber;

FIG. 3 is an Ellingham Diagram showing a hierarchy of oxidizers;

FIG. 4 is an Ellingham Diagram for a typical preheat environment; and

FIG. 5 is an Ellingham Diagram for a preheat equilibrium environment containing carbon monoxide/carbon dioxide at preheat ramp up temperatures.

### DETAILED DESCRIPTION

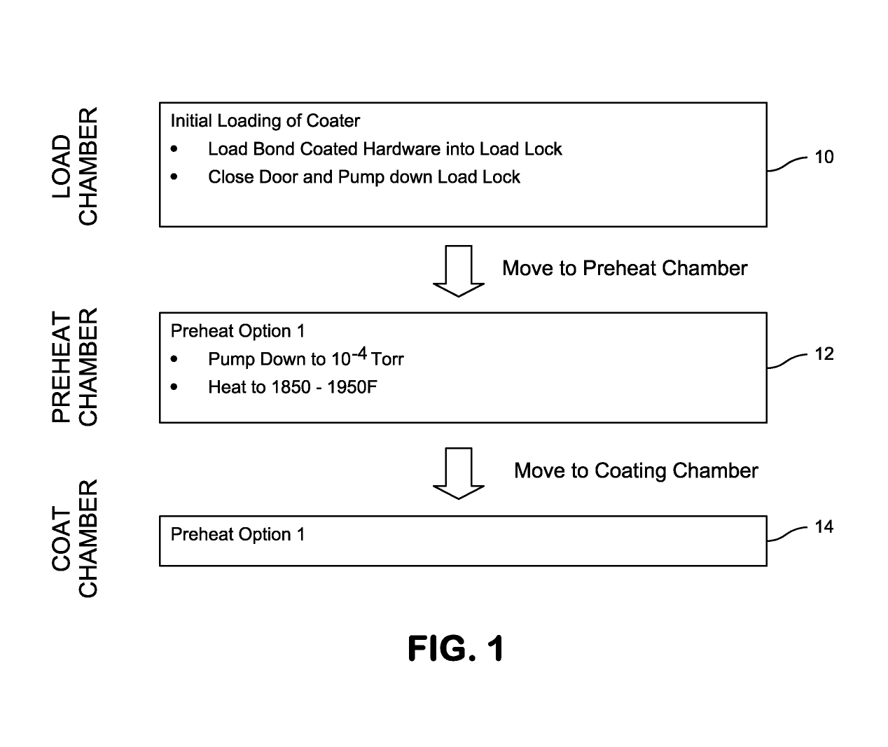

Referring now to the drawings, FIG. 1 illustrates a process for coating a part such as a turbine engine component. As shown in step 10, a load chamber is provided. Prior to being loaded into the load chamber, each part is provided with a bond coat such as a MCrAlY, aluminide, or platinum aluminide bond coat. One or more bond coated parts are placed into the load chamber. The door to the load chamber is closed and the load chamber is pumped down by a roughing pump to a desired pressure.

In step 12, the gate between the load chamber and a preheat chamber is opened. The bond coated parts are moved to a preheat chamber. In the preheat chamber, the atmosphere is pumped down so as to obtain a very low pressure on the order of 10⁻² Torr. Thereafter, the bond coated parts are heated to a temperature in the range of from 1800 to 2000 degrees Fahrenheit for a desired period of time using one or more heating elements.

After the bond coated parts have been preheated, the gate between the preheat chamber and the coating chamber is opened. The parts are then moved from the preheat chamber to an electron beam physical vapor coating chamber as shown in step 14. In the coating chamber, the outer coating or the thermal barrier coating may be applied to the bond coated substrate using an EB-PVD deposition technique.

In the process shown in FIG. 1, the preheat operation offers radiant heating to parts in a low pressure environment. The atmospheric composition is approximately 80% nitrogen and 19% oxygen. During the heat up, there is enough oxygen available to promote oxidation. Being radiant heating, the heating is slow and the bond coated parts spend significant time in the 700 to 1800 degree Fahrenheit temperature range—a temperature range which is conducive to mixed oxides developing on the surface of the bond coat prior to the deposition of the outer or thermal barrier coating.

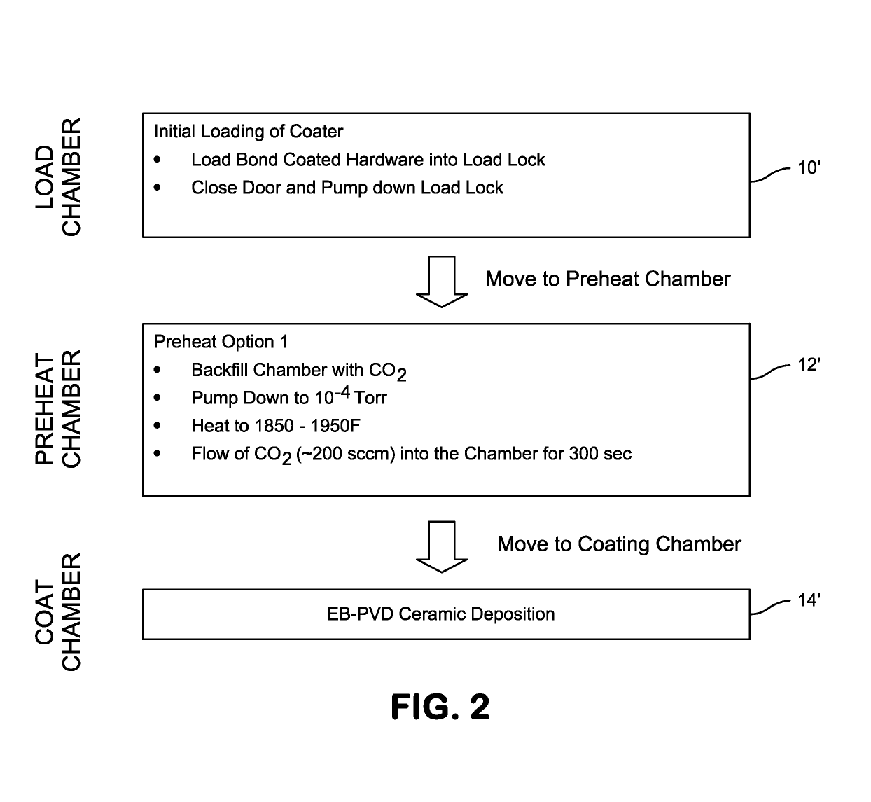

It has been found to be desirable to provide a protective atmosphere which avoids the development of such mixed oxides. A process for doing this is shown in FIG. 2. In particular, there is shown a coating process in which the preheat chamber is provided with a protective atmosphere.

In the process shown in FIG. 2, in step 10′, the bond coated parts are placed into a load chamber and treated as before. Thereafter, in step 12′, after the bond coated parts have been placed in the preheat chamber, the preheat chamber is backfilled with an oxidizer such as carbon dioxide, moist argon (dew point >−60° C.), or moist hydrogen (dew point >−60° C.). The chamber is then pumped down to a low pressure environment, e.g. a pressure in the range of from 10⁻² Torr to 10⁻⁵ Torr. The bond coated parts are then heated to a temperature in the range of 1800 to 2000 degrees Fahrenheit while in an atmosphere containing the protective gas. After reaching a temperature above 1832 degrees Fahrenheit, a flow of the reactive gas at a flow rate in the range of 50-500 sccm is introduced into the preheat chamber until ready for ceramic deposition.

After the preheating treatment is completed, as shown in step 14″, the preheated bond coated parts are moved to the coating chamber for deposition of an outer or thermal barrier coating formed from a suitable ceramic material such as zirconia or an yttria- or gadolinia-stabilized zirconia.

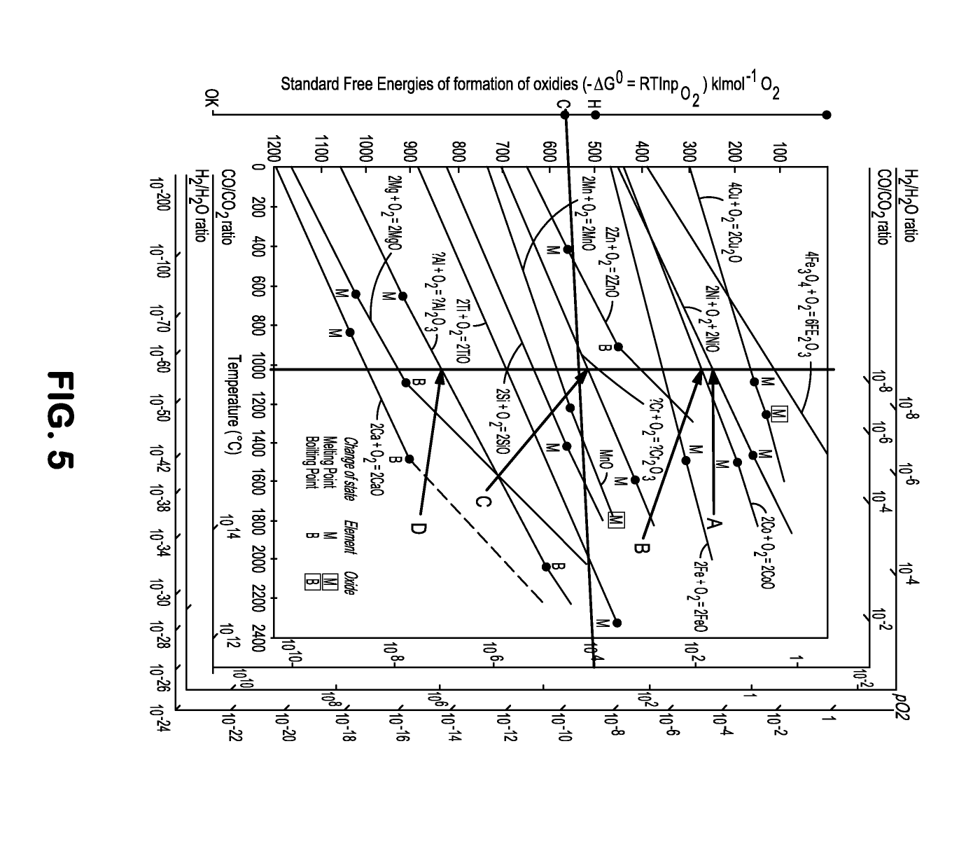

Carbon monoxide in the chamber may be the product of carbon dioxide reacting with carbon at high temperatures. During the preheat treatment described in connection with the process of FIG. 2, a carbon monoxide/carbon dioxide ratio atmosphere approach equilibrium, consuming most of the carbon dioxide, as the carbon heating elements and carbon based susceptors react with the carbon dioxide. Even with the significant consumption of the carbon dioxide (or, the formation of carbon monoxide) during the preheat process, the equilibrium ratio between these two species is 10,000 (FIG. 5) which is sufficient to promote only alumina formation and minimize the formation of metastable oxides of nickel, cobalt, chrome and aluminum during the preheat treatment at temperatures below 1800 F. Carbon monoxide, metallurgically speaking, is both a carburizing and mild reducing agent. Depending upon time, temperature, and pressure, carbon monoxide can be used as a protective environment, inhibiting the formation of undesirable oxides. Carbon dioxide, metallurgically speaking, is both a decarburizing and oxidizing agent. Depending upon time, temperature, and pressure, carbon dioxide can be used to preferentially develop specific oxides.

In introducing the carbon dioxide into the preheat chamber during step 12′, the flow rates should be maintained low so that even if the carbon dioxide reacts 100% with the heating elements in the preheat chamber, forming carbon monoxide, the loss would be negligibly small. Carburization conditions are maintained so that conditions not favoring carburization are maintained. For carbon monoxide to be carburizing, the partial pressure should be above 10⁻⁵ Torr.

To appreciate the benefits of a protective environment such as that offered by carbon dioxide, one can refer to its thermodynamic properties and the properties of the metallic constituents of a MCrAlY bond coat. In particular, one can appreciate that the relationship that carbon dioxide has with the development of nickel, chrome cobalt, and aluminum oxides. The following equation describes metal oxidation. The more negative the ΔG (free energy), the more favorable the reaction.

Metal+Oxygen→Metal Oxide, −ΔG (Energy of Formation)

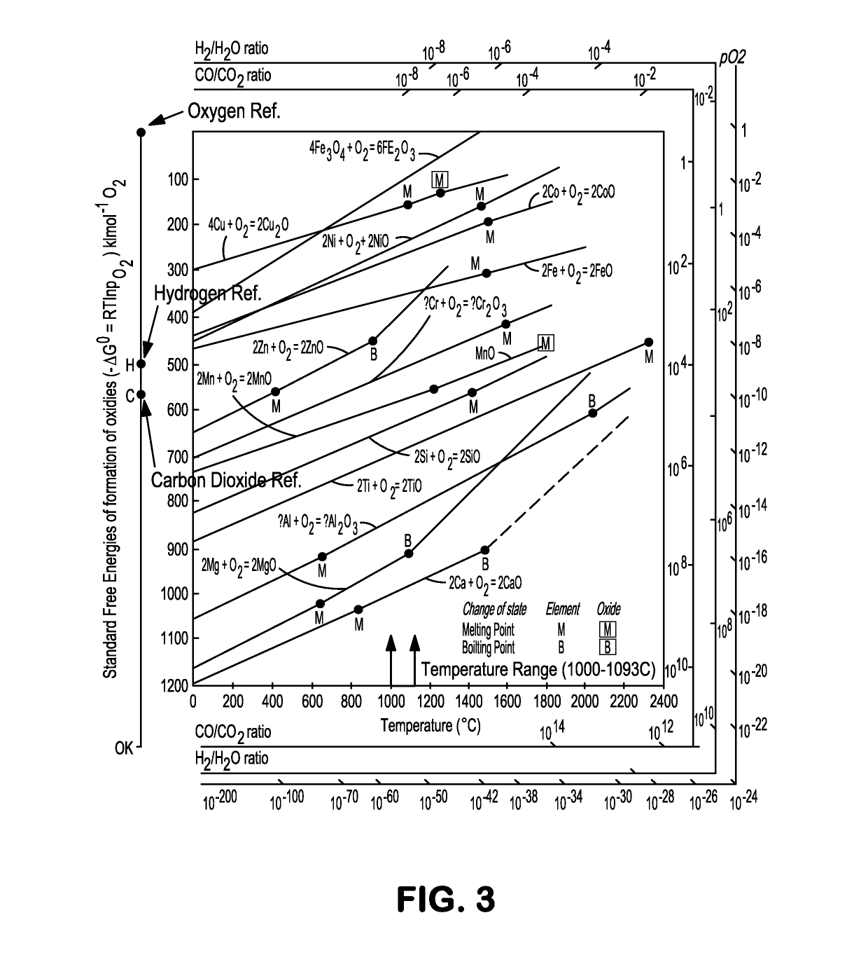

The Ellingham Diagram shown in FIG. 3 graphically summarizes the change in standard free energies associated with temperature and environments for the formation of various oxides. The Ellingham diagram is used to compare the equilibrium states of selected metal oxidation reaction. Or, in simple terms, whether or not the reaction is favorable. The Ellingham Diagram shows equilibrium relationships of various metal-metal oxide reactions through a range of temperatures in environments of oxygen, hydrogen and carbon dioxide. As can be seen from the diagram, carbon dioxide environments are lower than oxygen, yet sufficient to oxidize aluminum.

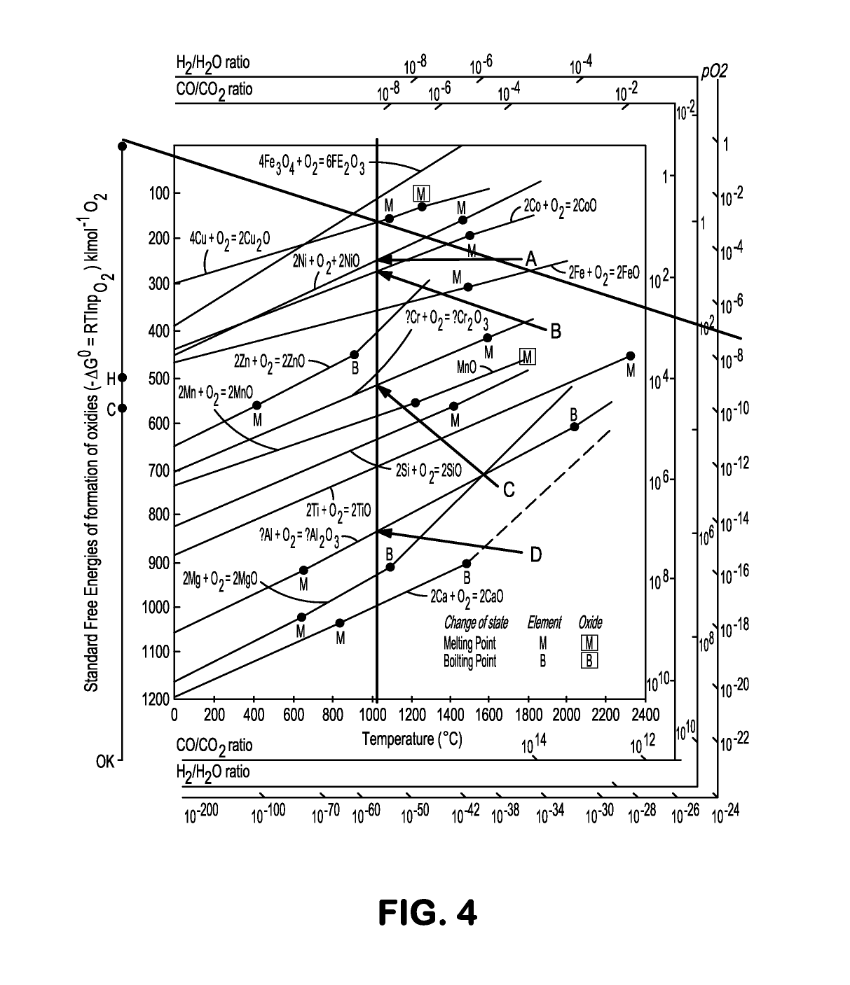

Referring now to FIG. 4, there is shown a typical oxygen preheat environment at 1832 degrees Fahrenheit (1000 degrees Centigrade) and a pressure of 10⁻⁴ Torr. The diagram shows equilibrium promoting the oxidation of nickel (A), cobalt (B), chrome (C), and aluminum (D) which are the main components of a NiCoCrAlY bond coat. To use the Ellingham Diagram, one connects a line between the appropriate reference point and the associated environmental condition. All of the metal-metal oxide reactions that fall below the intersection are favored.

Referring now to FIG. 5, there is shown a carbon monoxide/carbon dioxide preheat environment at 1832 degrees Fahrenheit (1000 degrees Centigrade) at a pressure of 10⁻⁴ Torr. The figure shows equilibrium at a carbon monoxide/carbon dioxide ratio of greater than 10⁴ (or >10,000). Only a very small percent of carbon dioxide is required to promote alpha alumina formation reaction (D) in the bond coat. To accelerate the kinetics of this reaction, slightly higher rations may be required. As can be seen from the diagram, only the formation of alumina is favored.

Carbon dioxide, backfilled into the preheat chamber prior to heat-up, displaces the air and provides a more protective atmosphere to minimize the growth of undesirable metastable oxides. The heating elements will react with the carbon dioxide, converting it to carbon monoxide. The carbon monoxide/carbon dioxide ratio will climb, producing an increasingly protective atmosphere as the temperature climbs and thereby inhibit the formation of metastable oxides. A high carbon monoxide/carbon dioxide ratio can protect Ni, Cr, Co and Al from forming oxides during preheat. The conditions will not favor carburization due to the low pressure within the preheat chamber.

A low flow carbon dioxide introduced into the preheat chamber at 1832 degrees Fahrenheit (1000 degrees Centigrade) and at low pressure (10⁻⁴ Torr) will lower the carbon monoxide/carbon dioxide ratio and thereby promote the growth of alpha alumina thermally grown oxide. Therefore, the thermally grown oxide control will be a factor of carbon dioxide flow. Control of the carbon dioxide flow will provide the oxidizer necessary for alpha alumina formation in the preheat chamber. As in preheat, carbon dioxide will tend to form 100% carbon monoxide at equilibrium. However, the preheat chamber is a dynamic system, with a flow of carbon dioxide in while the chamber is being simultaneously pumped out. The kinetics of the reaction to form the carbon monoxide are not fast enough to keep up with the flow rate of carbon dioxide.

Using the preheating treatment shown in FIG. 2, one can form a thermally grown oxide layer on a surface of the bond coat layer, which thermally grown oxide layer can be an alpha alumina TGO or a complex oxide of alumina layer.

There has been provided herein a preheat chamber oxidation process. While the preheat chamber oxidation process has been described in the context of the specific embodiments described herein, other unforeseen alternatives, modifications, and variations may become apparent to those skilled in the art having read the foregoing description. Accordingly, it is intended to embrace those alternatives, modifications, and variations which fall within the broad scope of the appended claims.

What is claimed is:

1. A process for coating a part comprising the steps of:
loading at least one bond coated part into a load chamber;
moving the at least one bond coated part from the load chamber to a preheat chamber;
subjecting said at least one bond coated part to a preheat treatment which causes a thermally grown oxide layer to form; and
moving said at least one bond coated part with said thermally grown oxide layer to a coating chamber.

2. The process of claim 1, further comprising backfilling said preheat chamber with a protective atmosphere.

3. The process of claim 2, wherein said backfilling step comprises backfilling said preheat chamber with carbon dioxide, moist hydrogen or moist argon as an oxidizer.

4. The process of claim 2, further comprising pumping down pressure within said preheat chamber to a level less than 10⁻² Torr.

5. The process of claim 4, wherein said preheat treatment subjecting step comprises heating said at least one bond coated part within said pretreatment chamber to a temperature in the range of 1800 to 2000 degrees Fahrenheit.

6. The process of claim 5, further comprising flowing said protective atmosphere into said preheat chamber after said temperature has risen above 1800 degrees Fahrenheit.

7. The process of claim 6, wherein said protective atmosphere flowing step comprises flowing carbon dioxide, or other oxidizing agent, into the preheat chamber.

8. The process of claim 7, wherein said carbon dioxide or other oxidizing agent is flowed into the preheat chamber at a rate, while maintaining a pressure in the range of 10⁻² to 10⁻⁵ Torr while in preheat, in the range of from 50 to 500 sccm.

9. The process of claim 1, wherein said TGO forming step comprises forming an alpha alumina TGO or a complex oxide of alumina layer.

10. The process of claim 1, further comprising forming a coating over said thermally grown oxide layer.

11. The process of claim 9, wherein said coating forming step comprises forming a ceramic coating.

12. A process for forming a bond coated part having a thermally grown oxide layer, comprising the steps of:
providing a bond coated part;
placing said bond coated part in a preheat chamber; and
subjecting said bond coated part to a preheat treatment which causes a thermally grown oxide to form.

13. The process of claim 12, wherein said subjecting step comprises flowing a protective gas into said preheat chamber when temperature in said preheat chamber has reached at least 1800 degrees Fahrenheit.

14. The process of claim 13, wherein said flowing step comprises flowing carbon dioxide into said preheat chamber.

15. The process of claim 13, wherein said flowing step comprises flowing moist argon into said preheat chamber.

16. The process of claim 13, wherein said flowing step comprises flowing moist hydrogen into said preheat chamber.

17. The process of claim 13, wherein said flowing step comprises flowing said protective gas at a flow rate in the range of 50 to 500 sccm during the initial ramp up to 1800° F.

18. The process of claim 13, further comprising backfilling said preheat chamber with said protective gas prior to heating said bond-coated part within said preheat chamber.

19. The process of claim 18, further comprising creating a pressure in the range of from 10⁻² to 10⁻⁵ Torr within said preheat chamber after said backfilling step.
